(19) United States
(12) Patent Application Publication
(10) Pub. No.: US 2005/0231292 A1
(43) Pub. Date: Oct. 20, 2005

(54) Jitter generator

(76) Inventors: Hiroshi Akahori, Hamamatsu-shi (JP); Minoru Maeda, Hamamatsu-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 11/082,483

(22) Filed: Mar. 17, 2005

(30) Foreign Application Priority Data
Mar. 31, 2004 (JP) P. 2004-103070

(51) Int. Cl. H03L 7/00

(52) U.S. Cl. 331/16

(57) ABSTRACT

In a jitter generator (phase modulator), worsening of phase noise is restrained and phase modulation accuracy is improved, and the phase modulation accuracy is improved by preventing a change in the detection sensitivity of the phase detector, if any, from affecting a change in the phase modulation index. Also, phase modulation is made possible without lowering the phase modulation accuracy even when an input phase signal increases. In a jitter generator using a PLL circuit, a quadrature modulator to which a modulation signal from a phase signal generator is provided is inserted to an input stage of a phase detector that constitutes the PLL circuit. In addition to this, an overflow detector that detects an overflow on an upper limit side or lower limit side of an analog/digital converter, a control unit that outputs a value for an effective region of the analog/digital converter on the basis of an output of the overflow detector, a digital/analog converter that coverts an output of the control unit to an analog signal, and an adder that adds an output of the digital/analog converter to the modulation signal, are provided.

### BACKGROUND OF THE INVENTION

1. Field of the Invention

This invention relates to a jitter generator that generates a jitter (that is, performs phase modulation) in a PLL system by using an quadrature modulator circuit.

2. Description of the Related Art

Conventionally, it is common to use a PLL (phase-locked loop) for generating a jitter (that is, performing phase modulation) in an analog system.

FIG. 15 shows a structure of a conventional jitter generator.

In FIG. 15, a phase detector denoted by 1, a loop filter denoted by 2, a voltage-controlled oscillator denoted by 3 and a second prescaler (prescaler 2) denoted by 4 form a PLL circuit.

As an adder 5 is additionally provided downstream from the phase detector 1 of the PLL circuit and a signal generated by a phase signal generator 6 is added by the adder 5, phase modulation is performed on a voltage-controlled oscillator output and an output signal (phase-modulated output signal) with a jitter added to a reference signal, which is an input signal, is acquired.

A first prescaler (prescaler 1) denoted by 7 arranged upstream from the phase detector is optional and it is inserted when necessary.

For a phase modulator using a PLL circuit based on an analog signal, JP-A-2000-323982 discloses a set of PLL circuit that has a high-speed follow-up circuit added thereto to have a sufficiently low cut-off frequency and follow a substantial change in the frequency of a reference signal at a high speed, and that perform high-speed follow-up without sacrificing jitter and wander restraining characteristics by separately and arbitrarily setting the cut-off frequency of the PLL circuit and the operating conditions of the high-speed follow-up circuit.

However, unlike this invention, JP-A-2000-323982 does not disclose generation of a jitter in a PLL system using an quadrature modulator circuit.

In the conventional jitter generator (phase modulator) using a PLL circuit, to generate a jitter of 3200 UI (unit intervals) or a wander of UI equal to or higher than 3200 as prescribed by ITU-T O.172 “Jitter and Wander measurement equipment for digital system which are based on the synchronous digital hierarchy (SDH)”, the value of the second prescaler must be large because the normal detection range of phase detector is limited (for example, with a detection range of ±2π, in the case of 3200 UI, the second prescaler needs to perform at least 1600 frequency divisions).

That is, as the frequency division value increases, the loop band by the PLL is narrowed and the phase noise restraining range of the voltage-controlled oscillator with respect to the reference signal is narrowed. As a result, only a modulation signal output having large phase noise can be taken out.

If the phase noise is large, a jitter due to the noise itself occurs and the original phase modulation becomes unstable, leading to deterioration in the accuracy.

Usually, a frequency range can be arbitrarily set for the voltage-controlled oscillator. Therefore, because of its nature, the phase noise characteristic is poorer than that of the reference signal.

Also, when the detection sensitivity of the phase detector changes, the phase modulation index changes and the phase modulation accuracy is lowered.

Moreover, when the detection characteristic of the phase detector is nonlinear with respect to the phase difference between two signals that should be compared, the phase modulation index with respect to the amplitude of a modulation input signal becomes nonlinear, too, and therefore the phase modulation accuracy is lowered.

It is an object of this invention to restrain the worsening of the phase noise and improve the phase modulation accuracy in the jitter generator (phase modulator).

It is another object of this invention to improve the phase modulation accuracy by preventing a change in the detection sensitivity of the phase detector, if any, from affecting a change in the phase modulation index.

It is still another object of this invention to improve the phase modulation accuracy by realizing a linear phase modulation index with respect to the amplitude of the modulation input signal even when the detection characteristic of the phase detector is nonlinear with respect to the phase difference between two signals that should be compared.

It is still another object of this invention to enable phase modulation without lowering the phase modulation accuracy even when an input phase signal increases.

### SUMMARY OF THE INVENTION

To achieve the foregoing objects, in a jitter generator using a PLL circuit, a quadrature modulator to which a modulation signal from a phase signal generator is provided is inserted to an input stage of a phase detector that constitutes the PLL circuit (claim 1).

In a jitter generator using a PLL circuit including a phase detector, a loop filter, a voltage-controlled oscillator and a prescaler, a quadrature modulator to which a modulation signal from a phase signal generator is provided is inserted upstream from the phase detector in a feedback circuit of the PLL circuit (claim 2).

In a jitter generator using a PLL circuit including a phase detector, a loop filter, a voltage-controlled oscillator and a prescaler, a quadrature modulator to which a modulation signal from a phase signal generator is provided is inserted to a reference signal input side of the phase detector (claim 3).

Moreover, in the jitter generator as claimed in one of claims 1 to 3, a prescaler is inserted upstream from the phase detector (claim 4).

Also, in the jitter generator as claimed in one of claims 1 to 4, the phase signal generator includes a modulation signal generating unit, an analog/digital converter that converts the modulation signal to a digital signal, a lookup table that outputs digital data of quadrature components I(t) and Q(t) of the modulation signal by using an output of the analog/digital converter as an address, and a digital/analog converter that converts data read out from the lookup table to an analog signal, and the phase signal generator outputs the quadrature components I(t) and Q(t) of the modulation signal (claim 5).

Also, in the jitter generator as claimed in one of claims 1 to 5, the phase signal generator has a modulation signal generating unit, an analog/digital converter that converts the modulation signal to a digital signal, a lookup table that outputs digital data of quadrature components I(t) and Q(t) of the modulation signal by using an output of the analog/digital converter as an address, an overflow detector that saves data of preset upper limit value and lower limit value of the analog/digital converter as data for defining an effective region, then compares the output of the analog/digital converter with the upper limit value and lower limit value and detects an overflow on the upper limit side or lower limit side, a control unit that outputs a negative (−) value for the effective region of the analog/digital converter when the output of the analog/digital converter has an overflow on the upper limit side and that outputs a positive (+) value for the effective region of the analog/digital converter when the output of the analog/digital converter has an overflow on the lower limit side, a digital/analog converter that converts an output of the control unit to an analog signal, and an adder that adds an output of the digital/analog converter to the modulation signal (claim 6).

In the jitter generator as claimed in claim 6, the control unit has an up-down counter that counts up or down in accordance with the overflow on the upper limit side and the overflow on the lower limit side of the output of the analog/digital converter, and when the up-down counter counts up, a negative (−) value for the effective region of the analog/digital converter is outputted, whereas when the up-down counter counts down, a positive (+) value for the effective region of the analog/digital converter is outputted (claim 7).

Also, in the jitter generator as claimed in claim 6, the control unit has an up-down counter that counts up or down in accordance with the overflow on the upper limit side and the overflow on the lower limit side of the output of the analog/digital converter, and a memory unit that stores a count value of the up-down counter, and when the output of the analog/digital converter has an overflow on the upper limit side, a negative (−) value for the effective region of the analog/digital converter multiplied by the number of times of overflow on the upper limit side is outputted, whereas when the outputs of the analog/digital converter has an overflow on the lower limit side, a positive (+) value for the effective region of the analog/digital converter multiplied by the number of times of overflow on the lower limit side is outputted (claim 8).

Moreover, in the jitter generator as claimed in one of claims 1 to 4, the phase signal generator includes a memory in which values of sin(V(t)) and cos(V(t)) corresponding to a modulation signal V(t) are stored in advance, and a digital/analog converter that converts data read out from the memory to an analog signal, and the phase signal generator outputs I(t) and Q(t) (claim 9).

Also, in the jitter generator as claimed in one of claims 1 to 4, the phase signal generator includes a digital signal processor that calculates digital data of I(t) and Q(t) signals from the modulation signal at a high speed, and a digital/analog converter that converts a calculation output from the digital signal processor to an analog signal, and the phase signal generator outputs I(t) and Q(t) (claim 10).

Moreover, in the jitter generator as claimed in one of claims 5 to 10, a low-pass filter is provided downstream from the digital/analog converter.

### BRIEF DESCRIPTION OF THE DRAWINGS

FIG. 1 is a view showing a structure of a jitter generator (phase modulator) according to this invention.

FIG. 2 is a view showing the relation of signals in a quadrature modulator.

FIG. 3 is a vector view showing phase modulation of V(t) by quadrature modulation.

FIG. 4 is a view showing an exemplary structure of a circuit provided in a phase signal generator, for acquiring an I(t) signal and a Q(t) signal.

FIG. 5 is a view for explaining the principle of quadrature modulation.

FIG. 6 is a diagrammatic view showing the principle for finding sin(V(t)) and cos(V(t)) by using a sine-lookup table (memory) and a cosine-lookup table (memory) shown in FIG. 4.

FIG. 7 is a view showing a structure of an exemplary application of the jitter generator (phase modulator) according to this invention.

FIG. 8 is a view showing the structure of an exemplary application of the jitter generator (phase modulator) according to this invention.

FIG. 9 is a diagrammatic view showing the principle for finding sin(V(t)) and cos(V(t)) by using a sine-lookup table (memory) and a cosine-lookup table (memory) in a phase signal generator shown in FIG. 8.

FIG. 10 shows an exemplary relation between the voltage of a phase signal V(t) and a ROM address in the phase signal generator shown in FIG. 8.

FIG. 11 is a view showing the structure of an exemplary application of the jitter generator (phase modulator) according to this invention.

FIG. 12 is a view showing another exemplary structure of the circuit provided in the phase signal generator, for acquiring an I(t) signal and a Q(t) signal.

FIG. 13 is a view showing still another exemplary structure of the circuit provided in the phase signal generator, for acquiring an I(t) signal and a Q(t) signal.

FIG. 14 shows application of the phase signal generator of FIG. 8 to the jitter generator of FIG. 11.

FIG. 15 is a view showing the structure of a conventional jitter generator (phase modulator).

### DETAILED DESCRIPTION OF THE PREFERRED EMBODIMENTS

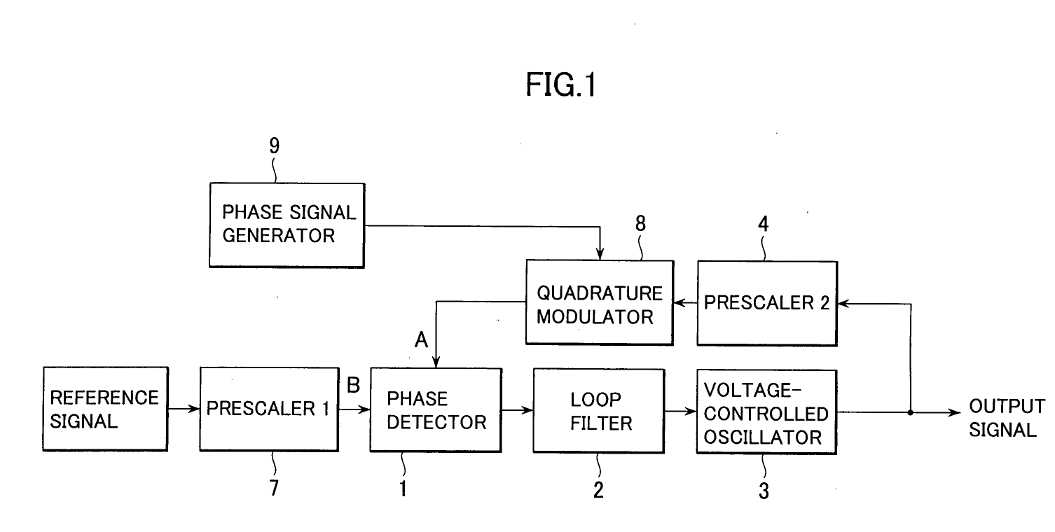

FIG. 1 is a view showing a fundamental structure of a jitter generator (phase modulator) according to this invention.

In FIG. 1, a phase detector denoted by 1, a loop filter denoted by 2, a voltage-controlled oscillator denoted by 3 and a second prescaler 4 form a PLL circuit.

In this invention, a quadrature modulator 8 is inserted into a feedback circuit part of PLL (that is, output side of the second prescaler 4). A modulated signal is provided to the phase detector and an output signal (phase-modulated signal) with a jitter added to a reference signal, which is an input, is acquired. However, when a dividing value of the second prescaler 4 is N, the output frequency and the jitter become an N value.

A first prescaler (prescaler 1) denoted by 7, arranged upstream from the phase detector, is optional and it is inserted when necessary.

In this case, since the PLL operates in such a manner that a quadrature modulation output A and an output B of the first prescaler 7 are of the same phase, even when the phase modulation of 3200 UI is performed, for example, if the phase modulation of 3200 UI is multiplied at the quadrature modulator, the second prescaler 4 can be set irrespective of that value. (The second prescaler 4 may perform one frequency division.)

In short, a broad loop band of the PLL can be set and the phase noise restraining range of the voltage-controlled oscillator with respect to a reference signal becomes broader. As a result, a signal output having smaller phase noise can be taken out.

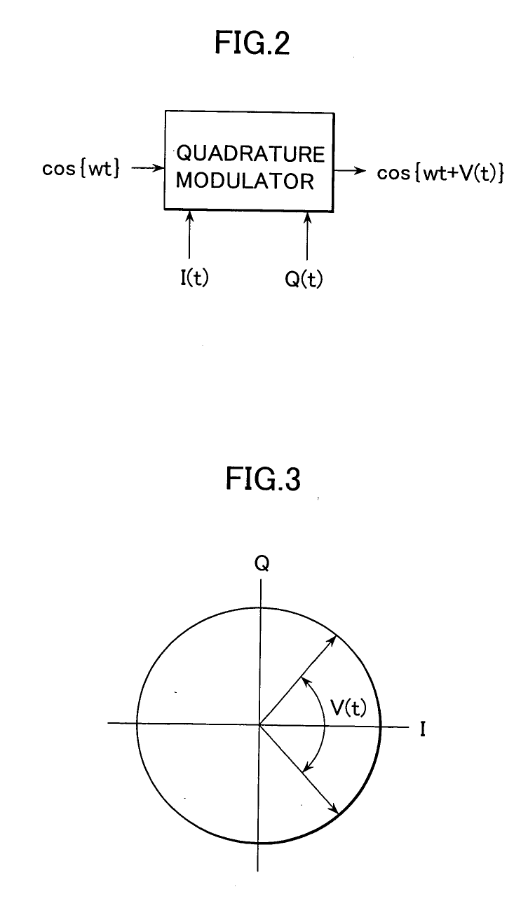

As the quadrature modulator 8 in FIG. 1, a quadrature modulator as shown in FIG. 2 is used. In FIG. 2, the quadrature modulator 8 generates a phase-modulated wave output cos{ωt+V(t)} by applying a phase modulation signal V(t) to a signal to be modulated cos{ωt}.

Quadrature modulation is a modulation technique in which a local signal (signal to be modulated) is separated into quadrature components, which are then modulated by modulation signals I(t) and Q(t), respectively, and combined, as shown in FIG. 5. Quadrature modulation itself is a conventional technique and quadrature modulation ICs are commercially available.

FIG. 3 is a vector view showing phase modulation of V(t) by quadrature modulation. By using such quadrature modulation, phase modulation can be directly performed on a carrier signal.

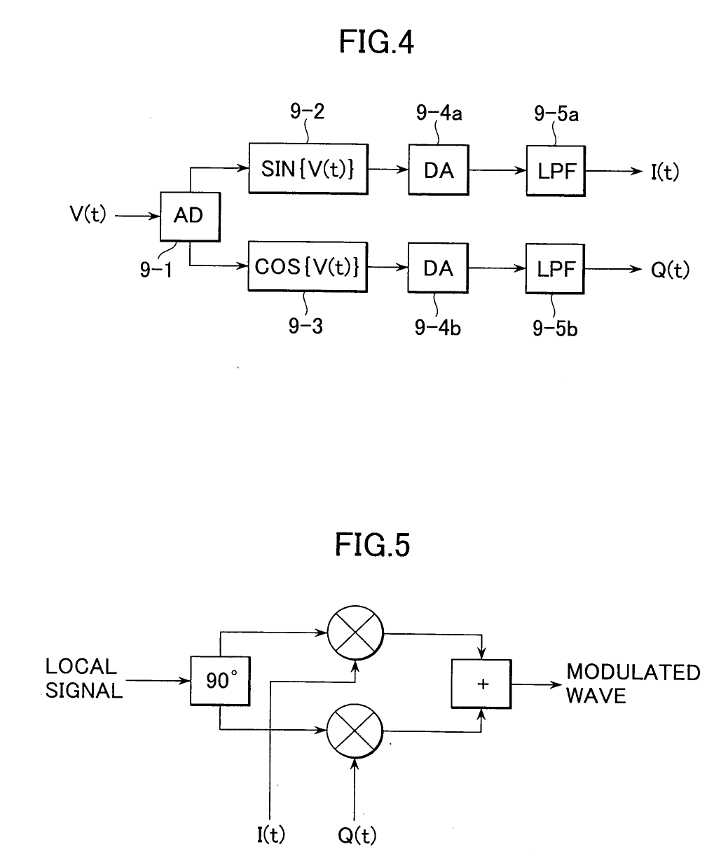

FIG. 4 is a view showing an exemplary structure of the circuit provided in the phase signal generator shown in FIG. 1, for acquiring the I(t) signal and Q(t) signal. The modulation signal V(t), which is an analog signal, is converted to a digital signal by an analog/digital converter 9-1 and then converted to a sin(V(t)) value and a cos(V(t)) value by a sine-lookup table (memory) 9-2 and a cosine-lookup table (memory) 9-3. After that, these values are converted to analog signals by digital analog converters 9-4a and 9-4b, and the I(t) signal and Q(t) signal are acquired through low-pass filters 9-5a and 9-5b for eliminating the sampling clock frequency.

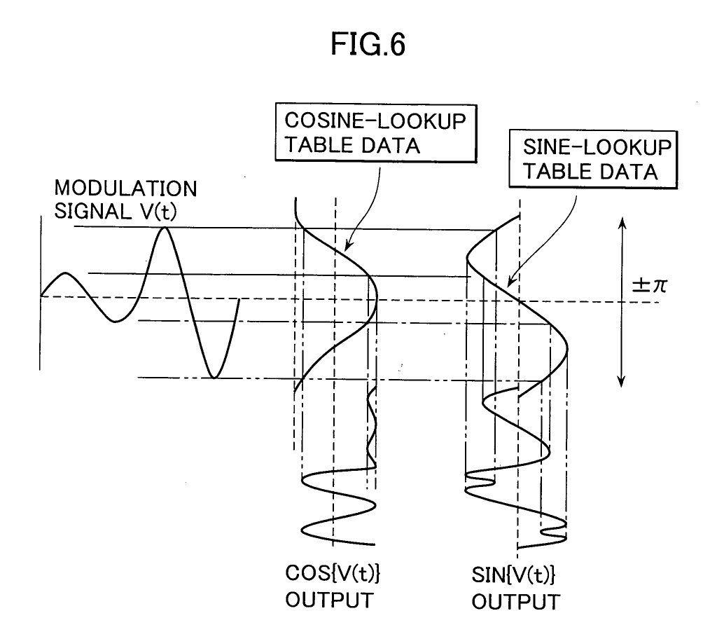

FIG. 6 is a diagrammatic view showing the principle for finding sin (V (t)) and cos (V (t)) by using the sine-lookup table (memory) 9-2 and the cosine-lookup table (memory) 9-3 of FIG. 4, in an example where phase modulation of the modulation signal V(t) is of 1 UI (phase modulation index=π) or less.

In FIG. 4, the analog/digital converter 9-1 performs analog/digital conversion of the inputted modulation signal V(t). The analog/digital-converted data become an address of the sine-lookup table (memory) and the cosine-lookup table (memory). And, each of the memory data is read out as a digital data of I(t) and Q(t). Therefore, when the modulation signal V(t) exceeds the dynamic range of the analog/digital converter, the lookup table cannot be used. That is, the lookup table contains only data of one cycle each and only phase modulation of 1 UI can be performed.

Even if an analog/digital converter of 10 bits is used, when lookup memory data is repetition of 2⁹ waveform data for two sets, phase modulation can only be extended up to 2 UI. An attempt to further extend phase modulation causes increase in the lookup memory data volume and it also reduces the signal level when modulation of small UI is to be performed. Therefore, the number of errors in the analog/digital conversion increases and the accuracy of phase modulation is lowered.

Moreover, while an increase in the number of frequency divisions in the first and second prescalers enables modulation of large UI, it leads to worsening of the phase noise as described above.

In order to address such a situation, when the modulation signal becomes larger (the UI value increases), similar processing is performed, using data acquired by repeating the data values in the sine- and cosine-lookup tables by the amount of increase in the UI value.

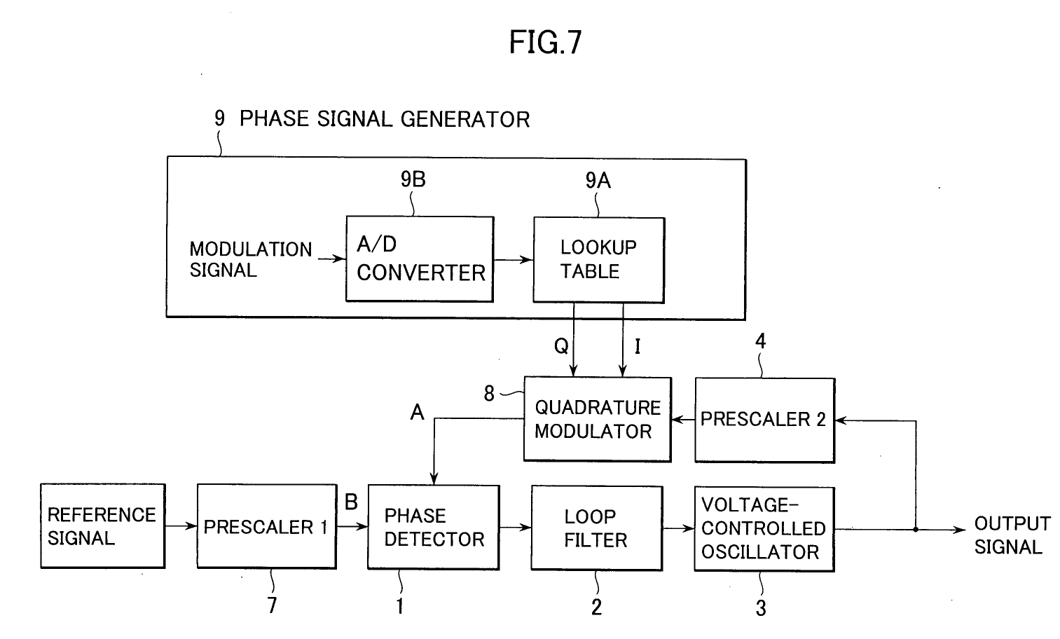

Hereinafter, an exemplary structure of operation in which when the modulation signal increases, the data values in the sine- and cosine-lookup tables are repeated by the amount of increase in the UI value, will be described. FIG. 7 specifically illustrates the structure of the phase signal generator 9 of FIG. 1. In FIG. 7, the phase signal generator 9 performs analog/digital conversion of a phase signal from a phase signal generating unit, not shown, by an analog/digital converter 9B, and generates I(t) and Q(t) signals by a lookup table 9A.

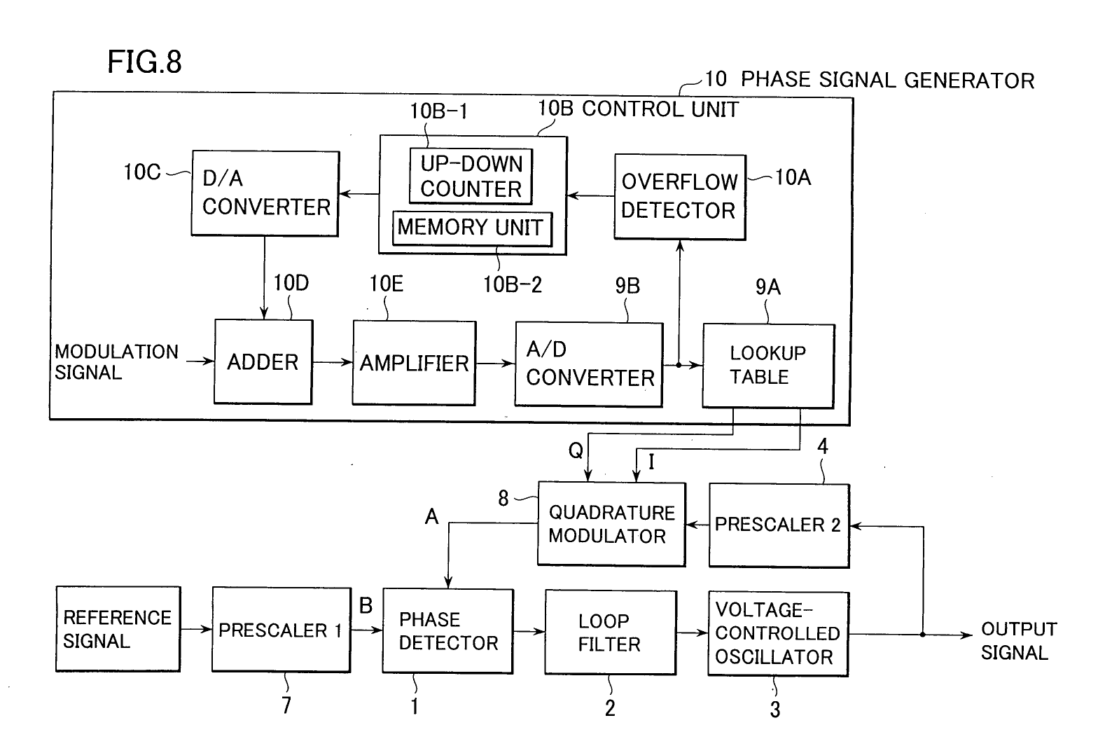

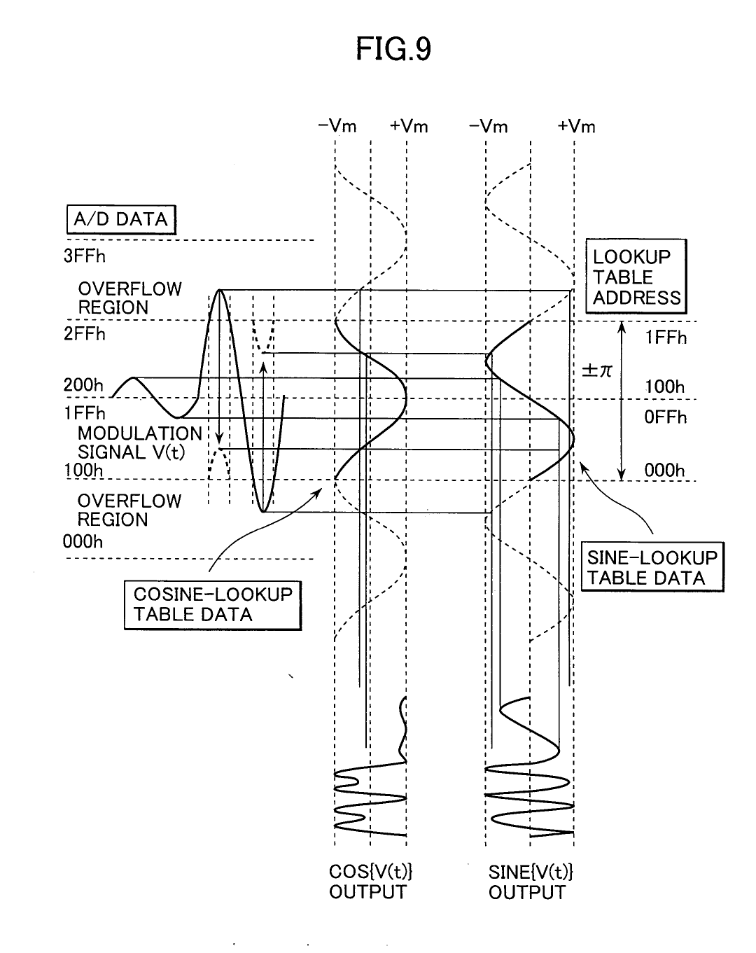

FIG. 8 is a structural view showing another embodiment of this invention. FIG. 9 is an explanatory view of the operation of the embodiment of FIG. 8. Hereinafter, this embodiment will be described with reference to FIGS. 8 and 9.

To address the case where data that is analog/digital-converted by an analog/digital converter 9B exceeds the dynamic range of the analog/digital converter 9B, a phase signal generator having a structure as shown in FIG. 8 is employed. In FIG. 8, a phase signal generator 10 has a structure in which excess of an inputted modulation signal over the dynamic range of the analog/digital converter 9B is detected by an overflow detector 10A and in which feedback is performed when the modulation signal exceeds the dynamic range and a lookup table 9A is referred to when the modulation signal no longer exceeds the dynamic range.

In FIG. 8, the analog/digital converter 9B uses, for example, 9 bits as a lookup memory address, acquired by excluding the least significant bit of a number of bits (in this example, 10 bits) that is one bit larger than the number of lookup memory address bits (in this example, 9 bits), and uses the upper 2 bits for detecting an overflow. FIG. 9 shows waveforms in the case where the analog/digital converter 9B has a 10-bit structure, with 2⁹ sine and cosine waveform data forming one cycle.

In this case, upper and lower quarter ranges of the analog/digital converter 9B are assumed to be overflow regions, and the remaining central half range is assumed to be an effective region and replaced by the lookup memory address. Therefore, the lookup memory address space and the effective region of the analog/digital converter 9B correspond to the same number of bits.

In FIG. 9, when it is detected by the overflow detector 10A that an inputted modulation signal V(t) has entered the overflow region, the range of the overflowing part is changed so that it becomes a signal indicated by a dotted line in FIG. 9, and it is processed to fall within the effective region of the analog/digital converter 9B.

Specifically, to shift the overflowing modulation signal to the effective region of the analog/digital converter 9B, when the overflow detector 10A has detected an overflow on a positive (+) side or on a negative (−) side, a control unit 10B generates a digital data of voltage corresponding to the effective region and a digital/analog converter 10C performs digital/analog conversion. Then, an adder 10D subtracts or adds the converted voltage from or to the input signal and reenters it to the analog/digital converter 9B.

Moreover, when the overflow detector 10A has detected an overflow, infinite amplitude can be handled in calculation by similarly providing another voltage corresponding to the effective region.

In FIG. 8, an up-down counter is provided in the control unit 10B to store the number of times of overflow on the upper side and the lower side. The number of times of overflow on the upper side and the lower side is thus managed.

With the above-described operation, lookup memory data is artificially repeated by using only lookup memory data of one cycle, so as to cope with a large UI value.

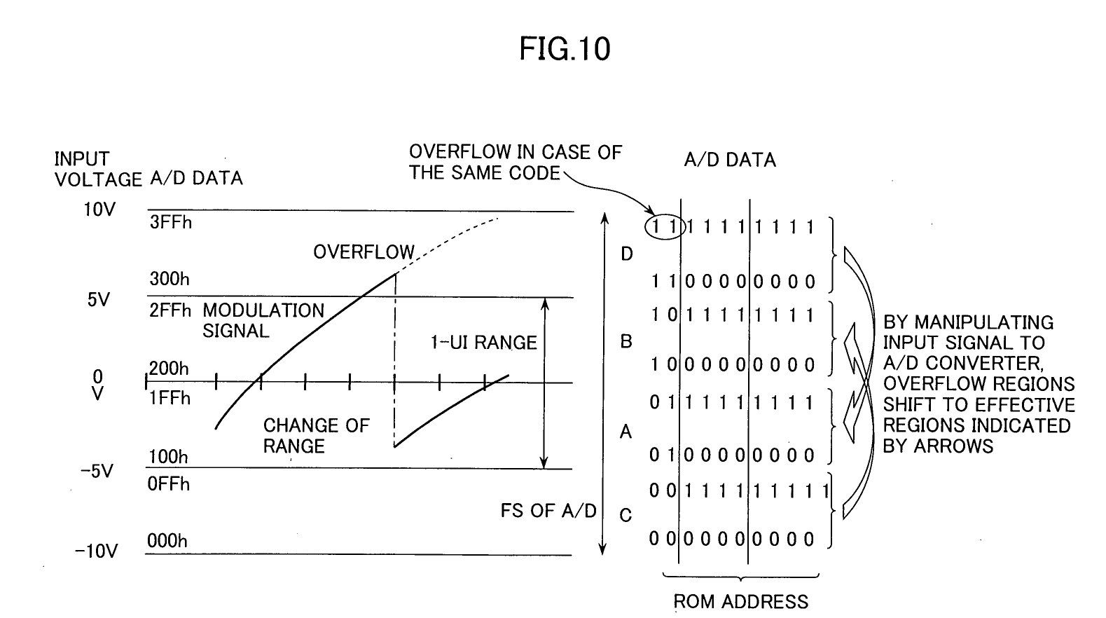

FIG. 10 is a view showing an exemplary relation between the voltage of the modulation signal V(t) and the lookup memory address. In the example shown in FIG. 10, the analog/digital converter 9B has a full scale ranging from +10 V to −10 V and its effective region ranges from +5 V to −5 V. The range from +5 V to −5 V is allocated to the lookup memory address and lookup memory data corresponding to 1 UI is used there.

In FIG. 10, output data from the analog/digital converter 9B consists of 10 bits and the range from +5 V to −5 V is used as the effective region (region A and region B). Therefore, the upper 2 bits of the 10 bits are used as bits for determining an overflow, and when these 2 bits are the same code, it is determined that there is an overflow. Region C is an overflow region on the lower side, and region D is an overflow region on the upper side.

In FIG. 10, when the modulation signal exceeds +5 V and overflows (into the region D), the up-down counter 10B-1 in the control unit 10B counts up the count value and this value is outputted to the digital/analog converter 10C. The digital/analog converter 10C outputs a voltage corresponding to the count value. In this case, −10 V is generated.

The modulation signal V(t) has −10 V added thereto by the adder 10D and thus shifts from the region D to the region A. When it overflows on the negative side, the up-down counter 10B-1 counts down the count value and this value is outputted to the digital/analog converter 10C. The digital/analog converter 10C outputs a voltage corresponding to the count value. In this case, +10 V is generated and the modulation signal shifts from the region C to the region B.

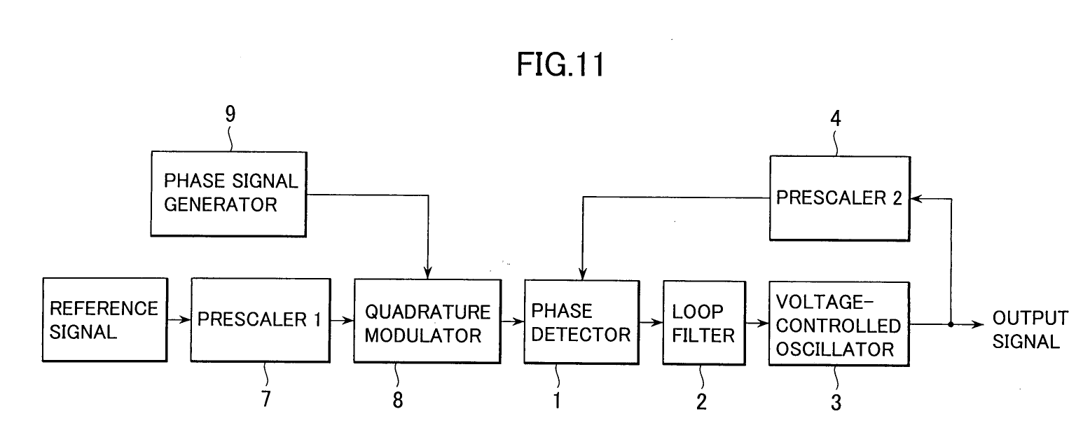

Next, an exemplary application of this invention will be described with reference to FIG. 11.

FIG. 11 is a view showing the structure of an exemplary application of the jitter generator (phase modulator) according to this invention. A phase detector denoted by 1, a loop filter denoted by 2, a voltage-controlled oscillator denoted by 3 and a second prescaler (prescaler 2) denoted by 4 form a PLL circuit.

In the exemplary application shown in FIG. 11, a quadrature modulator 8 is inserted immediately upstream from the phase detector 1 and a phase-modulated signal is provided to the phase detector 1. Thus, an output signal (phase-modulated signal) with a jitter added to a reference signal, which is an input, is acquired as in the case of FIG. 1.

A first prescaler 7 arranged upstream from the quadrature modulator 8 is optional and is inserted when necessary. The arrangement of the quadrature modulator 8 and the first prescaler 7 may be reversed (that is, the quadrature modulator 8 may be arranged upstream from the prescaler 7). In the jitter generator (phase modulator) shown in FIG. 11, even when the UI value of phase modulation of the reference signal increases, the second prescaler 4 can be set irrespective of that value.

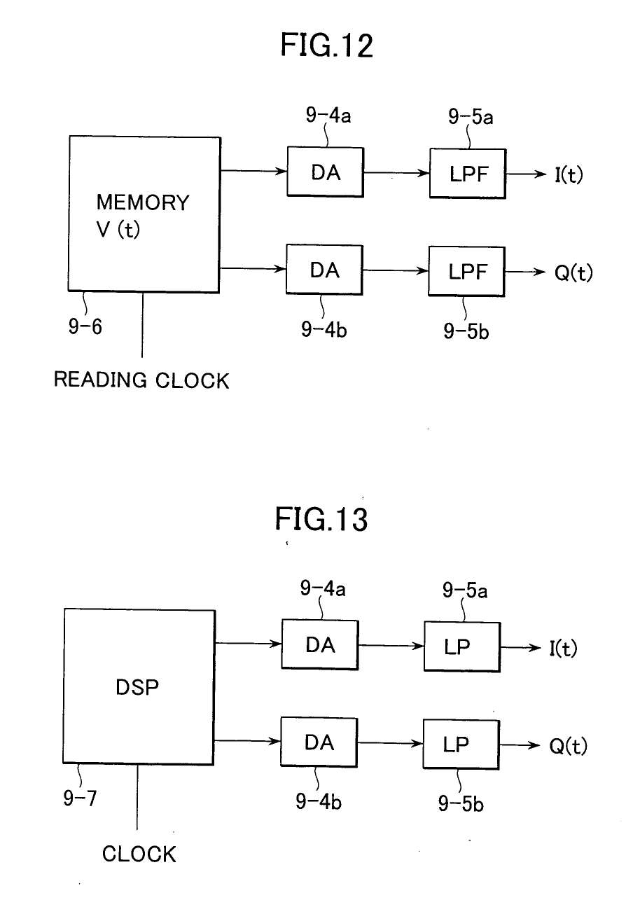

FIG. 12 is a view showing another structure of the circuit provided in the phase signal generator of FIG. 1, for acquiring the I(t) signal and Q(t) signal.

In FIG. 12, values corresponding to sin(V(t)) and cos (V (t)) of the modulation signal V(t) are written to a memory 9-6 in advance. These data are read out and converted to analog signals by digital/analog converters 9-4a and 9-4b, and the modulation signals I(t) and Q(t) are acquired through low-pass filters (LPF) 9-5a and 9-5b for eliminating the sampling clock frequency.

In this case, the I(t) and Q(t) signal speed may be acquired with the memory reading clock speed changed. Alternatively, the I(t) and Q(t) signal speed may be acquired with the write data value changed while maintaining a constant memory reading clock speed.

FIG. 13 is a view showing still another structure of the circuit provided in the phase signal generator of FIG. 1, for acquiring the I(t) signal and Q(t) signal. In FIG. 13, to generate the modulation signals I(t) and Q(t), a digital signal processor (DSP) 9-7 capable of high-speed operation is used for calculation to acquire data. The data are converted to analog signals by digital/analog converters 9-4a and 9-4b and the modulation signals I(t) and Q(t) are acquired through low-pass filters (LPF) 9-5a and 9-5b for eliminating the sampling clock frequency.

Since the frequency division value of the second prescaler can be reduced by the structures as described in claims 1 to 11, a broader loop band of PLL can be set and therefore the phase noise restraining range of the voltage-controlled oscillator with respect to a reference signal becomes broader. As a result, a signal output with small phase noise can be taken out and stable phase modulation can be performed. Thus, a jitter generator (phase modulator) with improved setting accuracy can be realized, achieving very high industrial applicability.

In FIG. 8, the exemplary structure is described in which every time an overflow occurs, the control unit 10B adds data so that the level of the modulation signal falls within the effective region of the analog/digital converter. However, it is also possible, for example, to broaden the overflow region to twice the effective region or more, recognize the overflow value in this state, divide the overflow value by the voltage of the effective region to calculate the count value, store the count value to the memory unit 10B-2, output the count value multiplied by the level for the effective region to the adder, and thus cause the level of the modulation signal to fall within the effective region of the analog/digital converter.

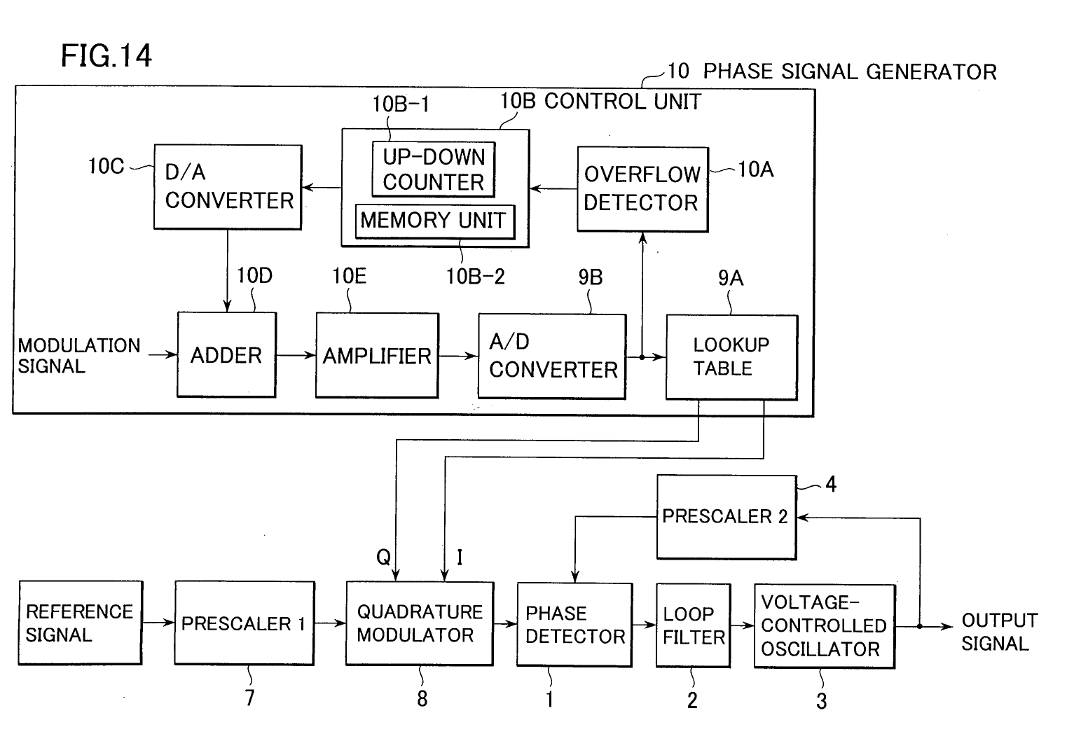

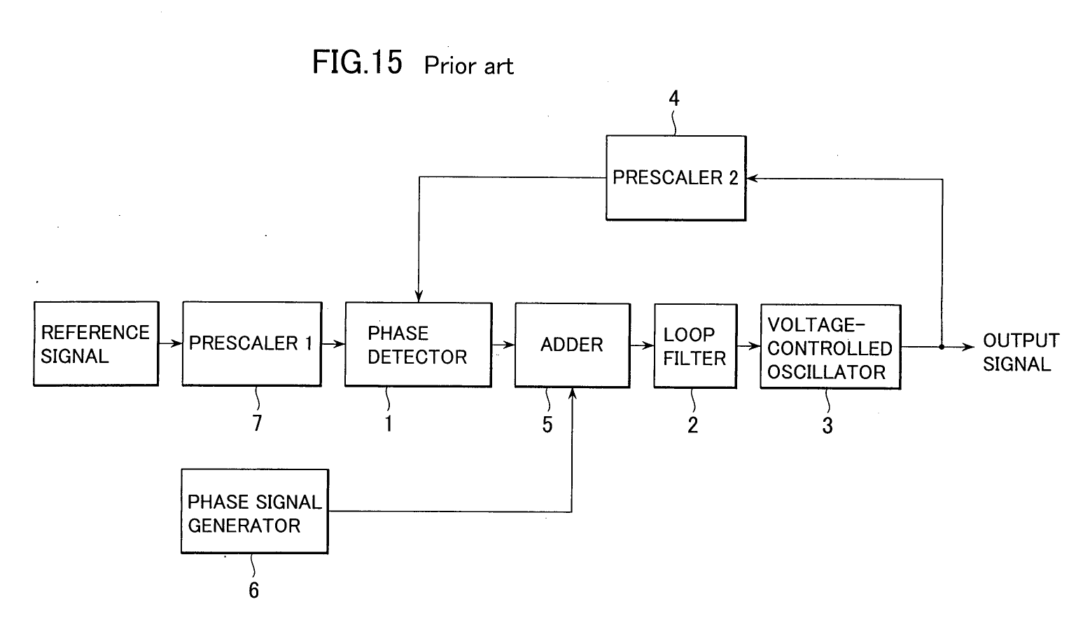

FIG. 14 shows application of the phase signal generator of FIG. 8 to the jitter generator of FIG. 11. In the structure shown in FIG. 14, a phase-modulated signal is provided to the phase detector, and an output signal (phase-modulated signal) with a jitter added to a reference signal, which is an input, is acquired as in the case of FIG. 1.

1. A jitter generator using a PLL circuit, wherein a quadrature modulator to which a modulation signal from a phase signal generator is provided is inserted to an input stage of a phase detector that constitutes the PLL circuit.

2. A jitter generator using a PLL circuit including a phase detector, a loop filter, a voltage-controlled oscillator and a prescaler,
wherein a quadrature modulator to which a modulation signal from a phase signal generator is provided is inserted upstream from the phase detector in a feedback circuit of the PLL circuit.

3. A jitter generator using a PLL circuit including a phase detector, a loop filter, a voltage-controlled oscillator and a prescaler,
wherein a quadrature modulator to which a modulation signal from a phase signal generator is provided is inserted to a reference signal input side of the phase detector.

4. The jitter generator as claimed in one of claims 1 to 3, wherein a prescaler is inserted upstream from the phase detector.

5. The jitter generator as claimed in any one of claims 1 to 3, wherein the phase signal generator includes:
a modulation signal generating unit;
an analog/digital converter that converts the modulation signal to a digital signal;
a lookup table that outputs digital data of quadrature components I(t) and Q(t) of the modulation signal by using an output of the analog/digital converter as an address; and
a digital/analog converter that converts data read out from the lookup table to an analog signal, and
wherein the phase signal generator outputs the quadrature components I(t) and Q(t) of the modulation signal.

6. The jitter generator as claimed in any one of claims 1 to 3, wherein the phase signal generator comprises:
a modulation signal generating unit;
an analog/digital converter that converts the modulation signal to a digital signal;
a lookup table that outputs digital data of quadrature components I(t) and Q(t) of the modulation signal by using an output of the analog/digital converter as an address;
an overflow detector that saves data of preset upper limit value and lower limit value of the analog/digital converter as data for defining an effective region, then compares the output of the analog/digital converter with the upper limit value and lower limit value and detects an overflow on the upper limit side or lower limit side;
a control unit that outputs a negative (−) value for the effective region of the analog/digital converter when the output of the analog/digital converter has an overflow on the upper limit side and that outputs a positive (+) value for the effective region of the analog/digital converter when the output of the analog/digital converter has an overflow on the lower limit side;
a digital/analog converter that converts an output of the control unit to an analog signal; and
an adder that adds an output of the digital/analog converter to the modulation signal.

7. The jitter generator as claimed in claim 6, wherein the control unit has an up-down counter that counts up or down in accordance with the overflow on the upper limit side and the overflow on the lower limit side of the output of the analog/digital converter, and when the up-down counter counts up, a negative (−) value for the effective region of the analog/digital converter is outputted, whereas when the up-down counter counts down, a positive (+) value for the effective region of the analog/digital converter is outputted.

8. The jitter generator as claimed in claim 6, wherein the control unit has an up-down counter that counts up or down in accordance with the overflow on the upper limit side and the overflow on the lower limit side of the output of the analog/digital converter, and a memory unit that stores a count value of the up-down counter, and when the output of the analog/digital converter has an overflow on the upper limit side, a negative (−) value for the effective region of the analog/digital converter multiplied by the number of times of overflow on the upper limit side is outputted, whereas when the outputs of the analog/digital converter has an overflow on the lower limit side, a positive (+) value for the effective region of the analog/digital converter multiplied by the number of times of overflow on the lower limit side is outputted.

9. The jitter generator as claimed in any one of claims 1 to 3, wherein the phase signal generator includes:
a memory in which values of sin(V(t)) and cos(V(t)) corresponding to a modulation signal V(t) are stored in advance; and
a digital/analog converter that converts data read out from the memory to an analog signal, and
wherein the phase signal generator outputs I(t) and Q(t).

10. The jitter generator as claimed in my one of claims 1 to 3, wherein the phase signal generator includes:
a digital signal processor that calculates digital data of I(t) and Q(t) signals from the modulation signal at a high speed; and
a digital/analog converter that converts a calculation output from the digital signal processor to an analog signal, and
wherein the phase signal generator outputs I(t) and Q(t).

11. The jitter generator as claimed in claim 5, wherein a low-pass filter is provided downstream from the digital/analog converter.
